(19) United States
(12) Patent Application Publication
(10) Pub. No.: US 2022/0416137 A1
(43) Pub. Date: Dec. 29, 2022

(54) METHOD FOR MANUFACTURING A SET OF LIGHT EMITTERS

(71) Applicant: ALEDIA, Echirolles (FR)

(72) Inventors: Frédéric MAYER, Voiron (FR); Ivan-Christophe ROBIN, Grenoble (FR); Erwan DORNEL, Champagnier (FR)

(21) Appl. No.: 17/776,915

(22) PCT Filed: Nov. 5, 2020
(86) PCT No.: PCT/EP2020/081059

§ 371 Date: May 13, 2022

(30) Foreign Application Priority Data
Nov. 15, 2019 (FR) 19 12800

(51) Int. Cl. H01L 33/62; H01L 25/075; H01L 33/00

(52) U.S. Cl. CPC H01L 33/62; H01L 25/0753; H01L 33/005; H01L 2933/0066

(57) ABSTRACT

Disclosed is a method for manufacturing a set of light emitters each including a light emitting structure and an electrical contact, the method including the steps of:—providing a wafer carrying a set of light emitting structures, each emitting structure being configured to emit a first radiation when an electric current flows through the emitting structure, and—manufacturing, for each emitting structure, an electric contact, the contact being electrically insulated from each other. The manufacturing includes:—forming a first set of at least two first contacts and at least one conductor, the contact of the first set being electrically connected to each other first contact of the one or the conductor,—injecting, for each contact belonging to the first set, a electric current through the contact and the corresponding emitting structure, and—observing a radiation emitted in response to the injection.

This application is the U.S. national phase of International Application No. PCT/EP2020/081059 filed Nov. 5, 2020, which designated the U.S. and claims priority to FR 19 12800 filed Nov. 15, 2019, the entire contents of each of which are hereby incorporated by reference.

### BACKGROUND OF THE INVENTION

### Field of the Invention

The present invention relates to a method for manufacturing a set of light emitters. The present invention further relates to a method for manufacturing a corresponding screen.

### Description of the Related Art

Many display screens have a set of light emitters that are used to form the image displayed on the screen. These emitters each play the role of a picture element or “pixel” (in particular when the screen is monochrome), or of a portion of such a picture element, called a “sub-pixel” (in particular when the screen is a colour screen, each pixel comprising sub-pixels of a different colour, the selective lighting of which makes it possible to modify the colour of the pixel).

These light emitters typically comprise a light emitting structure, such as a light emitting diode or liquid crystal backlighting system, for emitting the desired radiation, and electrical contacts for connecting the light emitting structure to a control circuit so as to electrically power the emitting structure when it is desired that the associated radiation be emitted. Thus, the contacts are necessarily electrically insulated from each other, so that the light emitters can be operated independently.

The light emitters are usually produced simultaneously in the form of a wafer with multiple light emitters, each contact being borne by one side of the wafer. The wafer is then either used as-is in a display screen, or cut to separate the emitters from each other, each of which is then integrated into a screen or other light device.

However, emitters often do not perform optimally. For example, defects in the manufacture of emitters may result in non-functional emitters. In other cases, some emitters will require electrical currents with higher intensities or voltages than the nominal performance emitters.

It is difficult to detect these anomalous emitters easily. This detection usually involves supplying power to each emitter and studying its behaviour when powered, including checking that the expected radiation is actually emitted, and what electric current is required to do so.

However, since the light emitters, and in particular their respective electrical contacts, are electrically isolated from each other, this detection is complex to achieve. This is because detection requires that each of the independent emitters be connected to a corresponding power source. This step is usually carried out at the end of the screen manufacturing method, when each of the emitters is connected to the control circuit, since this circuit is designed to supply each light emitter. However, detection is then very late, so that even a non-functional and ultimately rejected screen will have undergone a large number of steps before it is detected.

If the detection is carried out during manufacture, before the emitters are connected to the control circuit, the contacting of each of the electrical contacts with an electrical connector, in particular a connecting pin, risks damaging a large number of these contacts and thus reducing the reliability of the final device, or even generating defects at the end of manufacture if some of the damaged contacts are rendered non-functional.

### SUMMARY OF THE INVENTION

There is therefore a need for a method for manufacturing a set of light emitters that allows simple detection of an abnormal emitter at an early stage in the manufacture of the set.

For this purpose, a method is proposed for manufacturing a set of light emitters each comprising a light emitting structure, a first electrical contact and a second electrical contact, the method comprising the steps of:
providing a wafer carrying a set of light emitting structures, the wafer having a first face and a second face, the first face and the second face bounding the wafer in a direction normal to the wafer, each emitting structure being configured to emit a first radiation when an electric current flows through the emitting structure, and
manufacturing a first electrical contact and a second electrical contact for each emitting structure, the first contact being arranged on the first face, the first contact and the second contact being configured so that, when an electrical potential difference is imposed between the first contact and the second contact, an electrical current flows through the emitting structure, the first contacts being electrically insulated from each other.

The manufacturing step comprises:
a step of forming, on the first face, each first contact and at least one first conductor, a first set of at least two first contacts being defined, each first contact of the first set being electrically connected to each other first contact of the first set by the first conductor(s),
a first step of injecting, for each first contact belonging to the first set, a first electric current through said first contact and the emitting structure corresponding to said first contact, and
a first step of observing a radiation emitted by at least one emitting structure in response to the injection of the first electric current.

With the invention, the emitting structures of the first set are electrically connected in a simple manner to an electrical source since the associated first contacts are electrically connected to each other. Thus, it is not necessary to individually connect each first contact of the first set to the electrical source via a respective connector such as a wire or a pin. Only one such connector, in contact with one of these first contacts, with one of the first conductors or with the first contact pad, is needed to inject an electric current into each of the emitting structures of the first set.

In addition, the first contacts are less damaged during each injection step, as there is no need to apply an electrical connector against each of the first contacts: only one electrical connector is needed to power each first contact of the first set. The subsequent connection of each first contact to a control circuit when the corresponding light emitter is integrated in a lighting device is then of better quality and the reliability of the device integrating the light emitter 10 is improved.

According to particular embodiments, the method comprises one or more of the following features taken in isolation or in any combination that is technically possible:
the method further comprises, following the first observation step, a step of removing each first conductor.
the forming step comprises depositing on the first face a layer of electrically conductive material to form each first contact and each first conductor, each first conductor being removed in the removing step by etching said layer.
each first contact is arranged opposite the corresponding emitting structure.
A second set of first contacts is further defined comprising at least two first contacts, the first set and the second set being distinct, the forming step comprising the formation of at least one second conductor, each first contact of the second set being electrically connected to each other first contact of the second set by the second conductor(s), the method comprising furthermore a second step of injecting, for each first contact belonging to the second set, a second electric current through the first contact in question and the emitting structure corresponding to the said first contact, and a second step of observing, through the first face, a radiation emitted by at least one emitting structure in response to the injection of the second electric current.
the first set comprises a plurality of first subsets, the second set comprising a plurality of second subsets, the first contacts of each first or second subset being arranged along a line of said subset, each proper line extending in a first direction on the first face, the lines being parallel to each other and offset from each other in a second direction perpendicular to the first direction, the lines of the first and second subsets alternating in the second direction.
the forming step further comprises forming a first connection pad and a second connection pad on the first face, the first connection pad being electrically connected to each first conductor, the second connection pad being electrically connected to each second conductor, each first electrical current being injected via the first connection pad, each second electrical current being injected via the second connection pad.
the set of first contacts is interposed between the first connection pad and the second connection pad in the first direction,
the removal step comprises the removal of each second conductor,
each first contact belongs to the first or second set.
in the first observation step and/or, if applicable, in the second observation step, the emitted radiation is observed through the first face.
the first injection step and/or, if applicable, the second injection step comprises the modification of an intensity of the first current between a first value and a second value strictly greater than the first value.
each emitting structure comprises a light-emitting diode, each first electrical contact being in particular electrically connected to a cathode of the light-emitting diode.
the set of light emitters comprises a single second contact common to all light emitters.
the set of light emitters has a plurality of second contacts.
during the first injection step and/or, if applicable, the second injection step, at least two second contacts, in particular all second contacts, are electrically connected to one another.
the first observation step and/or, if applicable, the second observation step comprises a step of detecting a defective emitting structure.
the first observation step comprises measuring, for each first contact, a light intensity of radiation passing through the first face in an area surrounding the first contact, and detecting a defective emitting structure when the measured light intensity is strictly below a predetermined threshold.
the detection step involves storing, in a memory, information relating to the positioning of at least one defective emitting structure.
the method comprises a step of separating the light emitters from each other and a step of disposing of each light emitter that is defective according to the stored information.
the method further comprises a step of providing a control circuit, and a step of connecting the first electrical contact and the second electrical contact of each light emitter to the control circuit.
the connection step is carried out after the disposal step.

### BRIEF DESCRIPTION OF THE DRAWINGS

Characteristics and advantages of the invention will become apparent upon reading the following description, given only as a nonlimiting example, referring to the attached drawings, in which:

FIG. 1 is a partial schematic cross-sectional view of a first example of a set of light emitters according to the invention, each light emitter comprising at least one emitting structure and a first contact,

FIG. 2 is an enlarged cross-sectional view of a light emitter of FIG. 1, showing in particular an example of an emitting structure,

FIG. 3 is a view of one side of the set of light emitters of FIG. 1 showing the first light emitter contacts,

FIG. 4 is a flowchart of the steps of a method for manufacturing the first example of a set of light emitters, including a step of forming the first contacts,

FIG. 5 is a partial cross-sectional schematic view of the set of light emitters at the end of the step of forming,

FIG. 6 is a view of one side of the set of light emitters of FIG. 1 after the step of forming, showing the first contacts,

FIG. 7 is a view similar to FIG. 6 in a second example manufacturing method,

FIG. 8 is a view similar to FIG. 6 in a third example manufacturing method,

FIG. 9 is a view similar to FIG. 2 showing another example set of light emitters, and

FIG. 10 is a view of one face of the set of light emitters of FIG. 9 as they are after the step of forming.

### DETAILED DESCRIPTION OF PREFERRED EMBODIMENTS

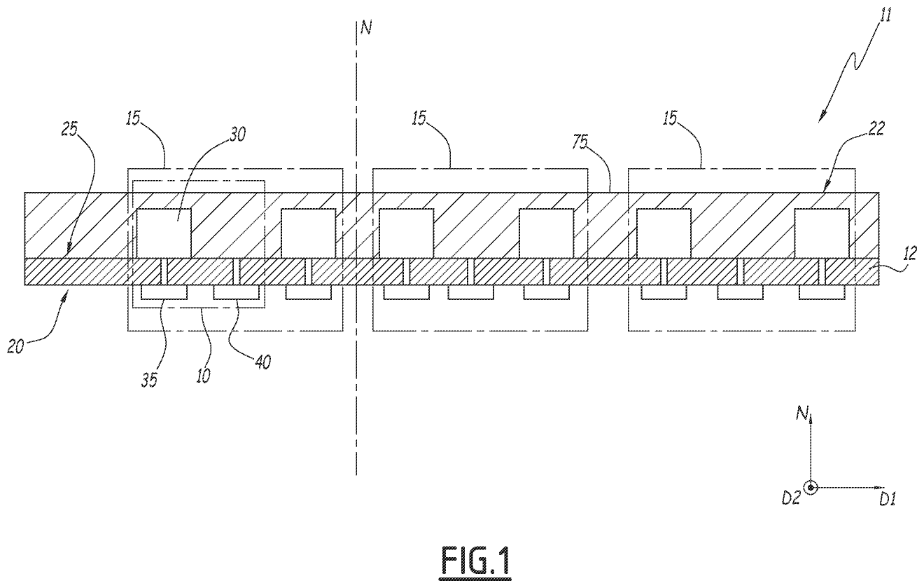

A first example of a set of light emitters 10 is depicted in FIG. 1.

The set of light emitters 10 includes, for example, a wafer 11 with each light emitter 10. The wafer 11 comprises, for example, a substrate 12 carrying each light emitter 10.

The wafer 11 has a first face 20 and a second face 22. The first face 20 and the second face 22 bound the wafer 11 in a direction normal to the wafer 11.

As an optional addition, a holding device (also known as a “handle”) intended to allow the wafer 11 to be gripped by an operator or robot is attached to the wafer 11. For example, the holding device is removably attached to the second face 22.

Each light emitter 10 is configured to emit a first radiation.

Each first radiation includes a first set of electromagnetic waves.

A wavelength is defined for each electromagnetic wave.

Each first set corresponds to a first wavelength range. The first wavelength ranges is the group formed by all wavelengths of the first set of electromagnetic waves.

A first average wavelength is defined for each first wavelength range.

Every first radiation is, in particular, visible radiation. An example of visible light is first radiation with a first average wavelength between 400 nanometres (nm) and 800 nm.

The set of light emitters 10 is, for example, intended to be integrated into a display screen. If so, each light emitter 10 is intended to form part of a picture element 15, also known as a “pixel”, or “sub-pixel” when the light emitter 10 is intended to emit one of a number of different colours that a single pixel is configured to emit.

The light emitters 10 of the set of light emitters 10 are, for example, intended to be integrated into a single display screen. In this case, the set of light emitters 10 and the substrate 12 carrying it are, in particular, integrated together with the display screen. In this case, the relative positioning of the light emitters 10 to each other is not changed when the light emitters 10 are integrated into the screen.

In one embodiment, the light emitters 10 are intended to be separated from each other, for example by a cut-out in the substrate 12, and then individually integrated into one or more separate displays. In this case, the same set of light emitters 10 may comprise light emitters 10 integrated into separate screens, and/or the relative positioning of the light emitters 10 with respect to each other may be altered when the light emitters 10 are integrated into the screen(s).

Each pixel 15 contains one or more neighbouring light emitters 10. For example, when the display is a monochrome display, each pixel 15 has a single light emitter 10.

When the display is a multicolour display, each pixel 15 comprises a plurality of light emitters 10, at least one of the light emitters 10 being configured to emit a first radiation having an average wavelength different from the average wavelengths of the other light emitters 10 of the same pixel 15.

In particular, at least one of the light emitters 10 is configured to emit a first blue radiation, at least one of the light emitters 10 is configured to emit a first green radiation and at least one of the light emitters 10 is configured to emit a first red radiation.

A first blue radiation has, for example, an average wavelength between 430 nm and 495 nm.

A first green radiation has, for example, an average wavelength between 500 nm and 560 nm.

A first red radiation has, for example, an average wavelength between 580 nm and 700 nm.

In the first example, each pixel 15 comprises four light emitters 10. For example, one of the light emitters 10 is configured to emit a first blue radiation, one of the light emitters 10 is configured to emit a first green radiation and the other two light emitters 10 are each configured to emit a first red radiation.

It should be noted that the number of light emitters 10 of each pixel 15 may vary.

Alternatively, each first radiation is identical to the other first radiations. For example, every first radiation is blue radiation, or ultraviolet radiation.

As an optional extra, each pixel 15 has a light converter for at least one of the light emitters 10.

Many types of light converters are used in the lighting industry, for example in fluorescent tubes. These light converters are often called “phosphors”.

The light converter consists of a conversion material.

The conversion material is configured to convert the first radiation emitted by the light emitter 10 into a second radiation. In other words, the conversion material is configured to be excited by the first radiation and to emit the second radiation in response.

The second radiation has a second wavelength range. The second range is separate from the first range. In particular, the second range has a second average wavelength, the second average wavelength being different from the first average wavelength. In particular, the second average wavelength is strictly greater than the first average wavelength.

The conversion material is, for example, a semiconductor material.

In other embodiments, the conversion material is a non-semiconductor material such as a doped yttrium aluminium garnet.

In particular, the conversion material may be an inorganic phosphorus.

Yttrium-aluminium garnet based particles (e.g. YAG:Ce), terbium-aluminium garnet (TAG)-based particles (e.g. TAG:Ce), silicate based particles (e.g. SrBaSiO4:Eu), sulphide based particles (e.g. SrGa2S4:Eu, SrS:Eu, CaS:Eu, etc.), nitride based particles (e.g. Sr2Si5N8:Eu, Ba2Si5N8:Eu, etc.), oxynitride based particles (e.g. Ba2Si5N8:Eu, etc.), nitride-based particles (e.g. Sr2Si5N8:Eu, Ba2Si5N8:Eu, etc.), oxynitride-based particles (e.g. Ca-a-SiAION:Eu, SrSi2O2N2:Eu, etc.), and fluoride-based particles (e.g. K2SiF6:Mn, Na2SiF6:Mn, etc.) are examples of inorganic phosphors.

Many other conversion materials can be used, such as doped aluminates, doped nitrides, doped fluorides, doped sulphides, or doped silicates.

The conversion material is, for example, doped with rare earth elements, alkaline earth elements or transition metal elements. Cerium is, for example, sometimes used for doping yttrium-aluminium garnets.

The light converter includes, for example, a set of particles P made of the conversion material. These particles P are sometimes called “luminophores”.

The substrate 12 is configured to carry each light emitter 10.

The substrate 12 is, for example, flat. In particular, the substrate 12 extends in a plane perpendicular to a normal direction X.

The substrate 12 has a third face 25. In addition, the first face 20 is a face of the substrate 12.

The substrate 12 is bounded in the normal direction N by the first face 20 and the third face 25.

Each of the first face 20 and the third face 25 is, for example, flat.

The substrate 12 is, for example, at least partially made of an electrically insulating material. The electrically insulating material is, for example, Al₂O₃, SiN, or SiO₂.

Each light emitter 10 comprises an emitting structure 30, a first contact 35 and a second contact 40.

Each emitting structure 30 is carried on the third face 25. For example, each emitting structure 30 extends from the third face 25 in the normal direction N.

The emitting structures 30 of the individual light emitters 10 form, for example, a two-dimensional grating in a plane perpendicular to the normal direction N, for example a square-mesh grating. Alternatively, the mesh is hexagonal, triangular or rectangular.

Each emitting structure 30 is, for example, a semiconductor structure. The term “semiconductor structure” means any structure consisting at least partially of a semiconductor material.

An example of a semiconductor structure is a stack of semiconductor layers stacked along the normal direction N. Such a structure is often referred to as a “two-dimensional structure”.

Other examples of semi-conductor structures are a three-dimensional semiconductor structure or a set of three-dimensional semi-conductor structures.

A lateral dimension is defined for each emitting structure 30. The lateral dimension is the maximum dimension of a contour surrounding the emitting structure 30 in a plane perpendicular to the normal direction N, while not surrounding any part of another emitting structure 30.

The lateral dimension is less than or equal to 20 microns (μm). For example, the lateral dimension is less than or equal to 10 μm. In one embodiment, the lateral dimension is less than or equal to 5 μm.

Each emitting structure 30 is configured to emit the first radiation from the light emitter 10 containing the emitting structure 30. For example, each emitting structure is an LED structure.

In particular, each emitting structure 30 is configured to emit the first radiation when the emitting structure 30 is passed through by an electric current, as will be explained in more detail below.

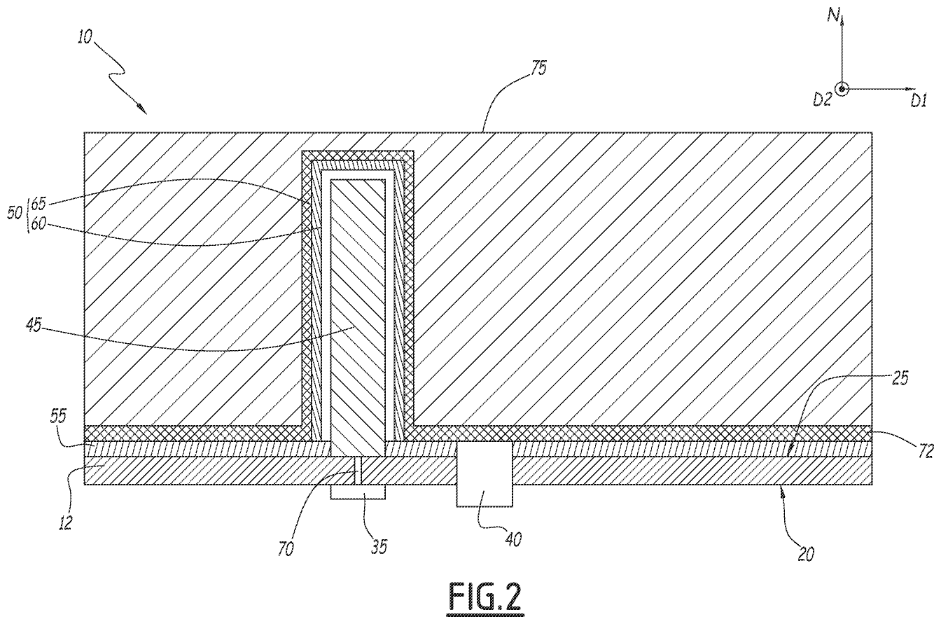

An example of a light emitter 10 with an emitting structure 30 is shown in FIG. 2.

The emitting structure 30 is, for example, a three-dimensional semiconductor structure. It should be noted that in some possible variants, the emitting structure 30 is a two-dimensional structure.

According to another embodiment, the light emitter 10 comprises a plurality of three-dimensional emitting structures 30, these emitting structures 30 being in particular identical to each other.

The emitting structure 30 extends from the third face 25 along the normal direction N.

The emitting structure 30 is, for example, a microwire.

The emitting structure 30 includes a core 45 and a cover layer 50.

The core 45 acts as either an n-doped layer or a p-doped layer. The core 45 is made of a semiconductor material called “core semiconductor material” in the following.

For example, the core semiconductor material is n-doped.

The core semiconductor material is, for example, GaN.

The core 45 is configured to support the cover layer 50.

The core 45 extends from the third face 25 along the normal direction N. In particular, the core 45 is electrically connected to the substrate 12.

The core 45 extends, for example, through an electrically insulating layer 55 covering part of the third face 25.

The core 45 is, for example, a cylinder.

A cylindrical surface is a surface consisting of all points on all lines that are parallel to a line and pass through a fixed plane curve in a plane that is not parallel to the line. A solid bounded by a cylindrical surface and two parallel planes is called a “cylinder”. When a cylinder is said to extend in a given direction, that direction is parallel to the line.

A cylinder has a uniform cross-section along the direction in which the cylinder extends.

The cross-section of the core 45 is polygonal. For example, the cross-section is hexagonal.

However, other shapes can be considered for the cross-section.

It should be noted that the shape of the core 45 may vary, for example if the emitting structure 30 is not a microwire.

A diameter is defined for core 45. The diameter is, in the case of a cylindrical core 45, the maximum distance between two points on the core 45 that are diametrically opposed in a plane perpendicular to the normal direction N.

When the core 45 has a hexagonal cross-section, the core diameter is measured between two opposite corners of the hexagon.

The diameter of the core 45 is between 10 nm and 5 μm.

A length measured along the normal direction N is defined for the core 45. The length is between 10 nm and 100 μm.

The core 45 has a top face and a side face.

The top face delimits the core 45 along the normal direction N. For example, the top face is perpendicular to the normal direction N.

The side face surrounds the core 45 in a plane perpendicular to the normal direction N.

The side face extends between the top face and the substrate 12. When the core 45 has a polygonal cross-section, the side face has a set of flat facets.

The cover layer 50 at least partially covers the core 45. For example, the cover layer 50 at least partially covers the top face of the core. In particular, the cover layer 50 completely covers the top face.

In the example shown in FIG. 2, the cover layer 50 at least partially covers the top face and at least partially the side face.

As can be seen in FIG. 2, the cover layer 50 completely surrounds the core 45 in a plane perpendicular to the normal direction N. In other words, the cover layer 50 forms a shell around the core 45.

The cover layer 50 includes at least an emitting layer 60 and a doped layer 65.

Each emitting layer 60 is configured to emit the first radiation when the electrical current passes through the emitting structure 30.

Each emitting layer 60 is interposed between the core 45 and the doped layer 65.

Each emitting layer 60 is made of a semi-conductor material.

For example, the cover layer 50 includes a stack of emitting layers 60 interposed between the core 45 and the doped layer 65.

Each emitting layer 60 is, for example, a quantum well. In particular, the thickness of each emitting layer 60 is, at any point of the emitting layer 60, between 1 nm and 200 nm.

When several superimposed emitting layers 60 are present, these emitting layers are, in particular, separated from each other by semi-conducting barrier layers, each barrier layer having a bandgap value strictly greater than the bandgap value of the emitting layers between which the barrier layer is interposed.

The thickness of each emitting layer 60 is measured, at any point on the emitting layer 60, along a direction perpendicular to the surface of the core 45 at the point on the surface of the core 45 closest to the point on the emitting layer 60.

For example, the thickness of each emitting layer 60 at a point on the emitting layer 60 that is aligned with a point on the core 45 along the normal direction N is measured along the normal direction N. The thickness of each emitting layer 60 at a point on the emitting layer 60 that is aligned in a plane perpendicular to the normal direction with a point on the core 45 is measured along a direction perpendicular to the nearest facet of the core 45.

Each emitting layer 60 is, for example, made of InGaN.

The doped layer 65 at least partially covers the emitting layer(s) 60.

Each doped layer 65 is made of a semi-conductor material.

The doped layer 65 acts as an n-doped layer or a p-doped layer of the LED structure.

The type of doping (n or p) in the doped layer 65 is opposite to the type of doping (p or n) in the core 45. For example, the doped layer 65 is p-doped.

The doped layer 65 is, for example, made of GaN.

Each first contact 35 is borne by the first face 20. In the remainder of this description, the term “first face 20” is used to refer to the face of the wafer 11 that bears the first contacts 35.

In particular, each first contact 35 is arranged opposite the emitting structure 30 belonging to the same light emitter 10 as the first contact 35. For example, the first contact 35 is aligned with the emitting structure 30 in the normal direction N.

It should be noted that embodiments in which there is an offset, in a plane perpendicular to the normal direction N, between the emitting structure 30 and the corresponding first contact 35, are also possible.

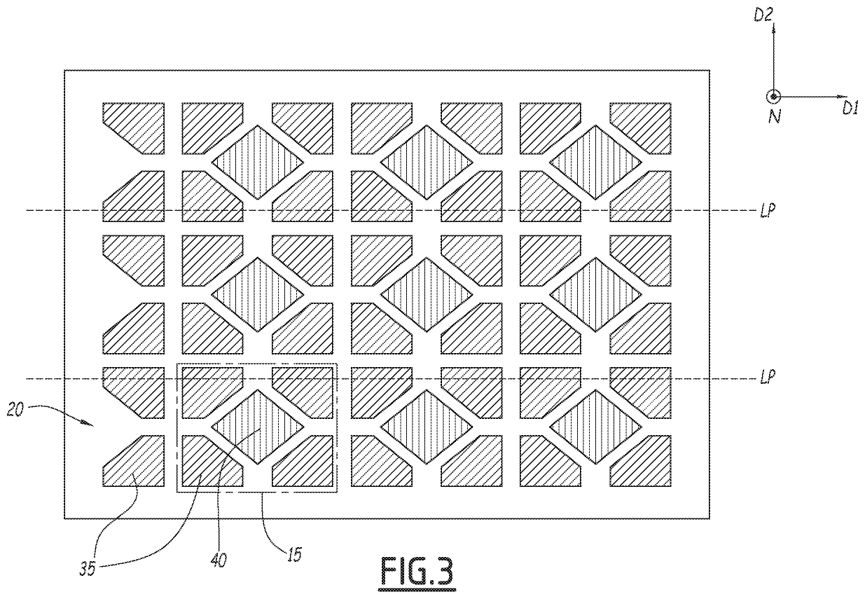

The first contacts 35 form a two-dimensional array on the first face 20, as shown in FIG. 3.

For example, the first contacts 35 form a two-dimensional square-mesh network. Alternatively, the mesh is hexagonal, triangular or rectangular.

In particular, the first contacts 35 are arranged along a set of lines LP, each line LP extending along a first direction D1. In particular, the first direction D1 is common to all lines LP.

The lines LP are offset from each other in a second direction D2. The second direction D2 is perpendicular to the first direction D1.

Each first contact 35 is electrically connected to the corresponding emitting structure 30. For example, the first contact 35 is electrically connected to the emitting structure 30 by an electrical conductor 70 accommodated in a conduit passing through the substrate 12 in the normal direction N.

In particular, each first contact 35 is electrically connected to a cathode of the emitting structure 30. For example, each first contact 35 is electrically connected to an n-doped region of the emitting structure 30, in particular to the core 45.

In one variant, each first contact 35 is electrically connected to an anode of the emitting structure 30. For example, each first contact 35 is electrically connected to an n-doped region of the emitting structure 30, in particular to the doped layer 65.

Each first contact 35 is electrically isolated from the other first contacts 35. For example, a distance, in a plane perpendicular to the normal direction N, between two neighbouring first contacts 35 is between 0.5 μm and 1 millimetre (mm).

A rate of coverage of the first face 20 by the first contacts 35 is defined. The coverage rate is the ratio between, in the numerator, the total surface area of the first contacts 35 and, in the denominator, the surface area of a portion of the first face 20 delimited by a closed contour surrounding each first contact 35 in a plane perpendicular to the normal direction N and tangent to the first contacts 35 which are disposed on a perimeter of the set of first contacts 35.

The coverage rate is between 1% and 99%. For example, the coverage rate is between 15% and 80%.

Each first contact 35 is made of an electrically conductive material. In addition, each first contact 35 is, for example, made of a material suitable for reflecting the first radiation.

For example, each first contact 35 is made of a metallic material. For example, each first contact 35 is made of aluminium. However, other electrically conductive materials can be considered, including silver, copper, gold, titanium, nickel, tantalum and tungsten.

In FIG. 3, each first contact 35 is shaped like an irregular pentagon. It should be noted that the shape of the first contacts 35 may vary.

Each first contact 35 has a thickness, measured in the normal direction N, of between 50 nm and 100 μm.

Each second contact 40 is, for example, arranged on the first face 20. Alternatively, the second contact is arranged on the third face 25.

Each second contact 40 is configured so that when an electrical potential difference is applied between the first contact 35 and the second contact 40, an electrical current flows through the emitting structure 30. In particular, the electric current flows through the core 45, the emitting layer(s) 60 and the doped layer 65.

Each second contact 40 is, for example, electrically connected to the cover layer 50, in particular to the doped layer 65. If it is, the second contact 40 is electrically connected to an anode of the emitting structure 30.

For example, each second contact 40 is electrically connected to the cover layer 50 by a connection layer 72.

The connection layer 72 is made of an electrically conductive material. For example, the connection layer 72 is made of a transparent material. In particular, the connection layer 72 is made of indium-tin oxide (also called ITO).

The connection layer 72 at least partially covers the cover layer 50 and the insulating layer 55 and is electrically connected to the second contact 40 through the substrate 12.

The connection layer 72 has, for example, a thickness of between 10 nm and 2 μm.

The second contact 40 is, for example, common to each of the light emitters 10 of a single pixel 15, as seen in FIG. 3. For example, each second contact 40 is arranged between the first four contacts 35 corresponding to four light emitters 10 of a single pixel 15. However, the location of the second contact 40 relative to the first contacts 35 may vary.

In one embodiment, the second contact 40 is common to each of the light emitters 10 in the set of light emitters 10. In this case, the set of light emitters 10 comprises, for example, a single second contact 40.

In another embodiment, each light emitter 10 has a second contact 40 that is separate from the second contacts 40 of the other light emitters 10.

Each second contact 40 is, for example, electrically connected to every other second contact 40 in the set of light emitters 10. For example, the connection layer 72 is common to each of the light emitters 10 in the set of light emitters 10. In particular, the connecting layer 72 covers the entire insulating layer 55 and the entirety of each cover layer 50. In this case, the connecting layer 72 is, in particular, a conforming layer applied to the emitting structures 30 and the insulating layer 55 after the emitting structures 30 and the insulating layer 55 have been manufactured.

Each second contact 40 is made of an electrically conductive material, for example a metallic material. For example, each second contact 40 is made of aluminium. However, other electrically conductive materials can be considered, including silver, gold, titanium, copper, nickel, tantalum and tungsten.

In a particular embodiment, each second contact 40 is made of the same material(s) as each first contact 35.

As shown in FIG. 2, each light emitter 10 comprises, for example, a layer 75, with each emitting structure 30 being embedded in the layer 75.

In this case, each connection layer 72 is interposed between the layer 75 and the substrate 12, and between the emitting structure 30 and the layer 75.

The layer 75 is made of an electrically insulating material such as SiN or SiO₂.

In particular, the layer 75 has a height greater than or equal to the height of each emitting structure 30, measured in the normal direction N.

The second face 22 is, for example, a side of the layer 75. The layer 75 is then delimited in the normal direction N by the second and third faces 22 and 25.

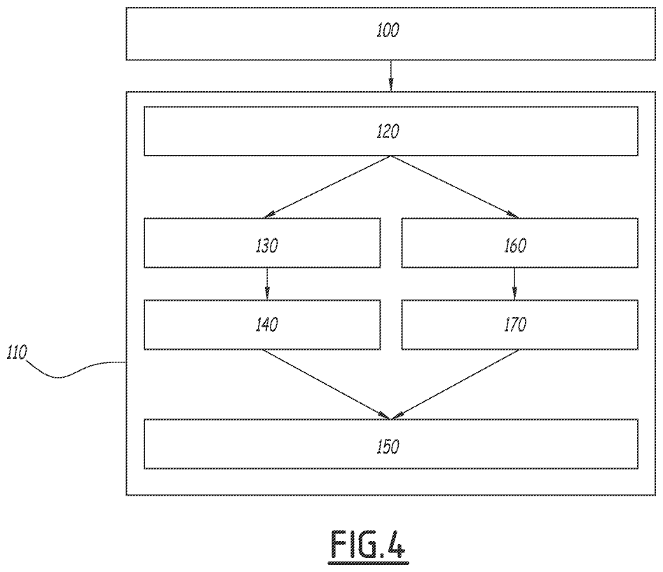

A first example of a manufacturing method for a set of light emitters 10 will now be described with reference to FIG. 4, which shows a flowchart of the steps in this manufacturing method.

The method comprises a supply step 100 and a manufacturing step 110.

In the supply step 100, the substrate 12 and the emitting structures 30 carried by the substrate 12 are supplied.

For example, the substrate 12, carrying the electrically insulating layer 55, is inserted into a material deposition chamber, and the emitting structures 30 are formed on the substrate 12 by material deposition techniques.

In one embodiment, the substrate 12 is provided in the form of a wafer supporting the electrically insulating layer 55, the emitting structures 30 and optionally the layer 75 are then formed on the third face 25, and the substrate 12 is then refined to reveal the first face 20.

In particular, the substrate 12 has a thickness of between 100 nm and 1 mm after refinement.

The refining is, in particular, carried out by a mechanical or mechanical/chemical polishing process, or by reactive ion etching.

In particular, the electrically insulating layer 55 has a plurality of holes through which the third face 25 is exposed, and which are intended to allow the formation of the cores 45 on the third face 25 while preventing the growth of core material on the electrically insulating layer 55.

In particular, each core 45 is formed, with the emitting layer(s) 60 and the doped layer 65 being subsequently formed on the core 45.

For example, metal organic chemical vapour deposition (MOCVD) is a means of obtaining emitting structures 30. In particular, this means microwire cores 45 can be obtained, especially when the material is selectively deposited in the holes of the electrically insulating layer 55.

MOCVD is also known as “MOVPE”, which stands for “metalorganic vapour-phase epitaxy”. Other chemical vapour deposition (CVD) processes can also be considered.

However, other deposition techniques can be used, for example molecular beam epitaxy (MBE), gas source MBE (GSMBE), metal organic molecular beam epitaxy (MOMBE), plasma-assisted molecular beam epitaxy (PAMBE), atomic layer epitaxy (ALE) or hydride vapour phase epitaxy (HVPE).

In the manufacturing step 110 the first contacts 35 and the second contacts 40 are manufactured.

The manufacturing step 110 comprises a forming step 120, a first injection step 130, a first observation step 140, and a removal step 150.

Optionally, the manufacturing step 110 further comprises a second injection step 160 and a second observation step 170.

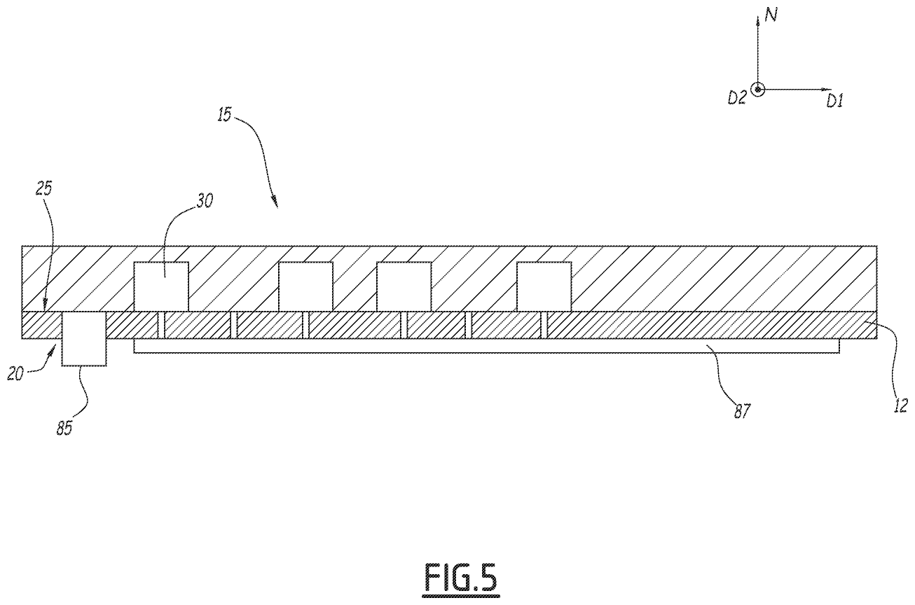

The state of the set of light emitters 30 at the end of the forming step 120 is shown in FIG. 5.

In the forming step 120, each first contact 35 is formed on the first face 20. Optionally, each second contact 40 is further formed on the first face 20.

In addition, at least one first conductor 80A is formed on the first face 20, for example a set of first conductors 80A. Optionally, at least a first connection pad 82A is also formed.

In one embodiment, a third contact 85 is further formed.

Each first contact 35 is, for example, formed by deposition, on the first face 20, of one or more electrically conductive layers 87 superimposed along the normal direction N. In particular, each first contact 35, each first conductor 80A, and, optionally, each second contact 40, each third contact 85 and/or the first connection pad 82A, are formed by deposition of such electrically conductive layer(s) 87.

Each electrically conductive layer 87 is made of the electrically conductive material(s) intended to form each first contact 35, each first conductor 80A, and, optionally, each second contact 40, each third contact 85 and/or the first connection pad 82A.

For example, the electrically conductive layer(s) 87 are deposited by a vacuum deposition technique, for example by vacuum evaporation.

In particular, the manufacturing step 120 comprises the deposition, on the first face 20, of a first mask at least partially covering the first face 20, and delimiting a set of exposed portions of the first face 20. The material(s) to form each first contact 35, each first conductor 80A and, optionally, each second contact 40, the third contact 85 and/or the first connection pad 82A, are then deposited on the first mask and on the exposed portions.

The first mask is then removed, for example by plasma etching or by chemical dissolution in a solvent bath.

Following removal of the first mask, the materials deposited on the exposed portions form at least each first contact 35, each first conductor 80A and, optionally, each second contact 40, the third contact 85 and/or the first connection pad 82A, while the materials deposited on the first mask are removed with the first mask.

Thus, each first contact 35, each first conductor 80A, and, optionally, each second contact 40, the third contact 85 and/or the first connection pad 82A, has a thickness common to each first contact 35, each first conductor 80A, and, optionally, each second contact 40, the third contact 85 and/or the first connection pad 82A.

A first set of first contacts 35 is defined for the first contacts 35 formed at the end of the forming step 120. As will be seen below, the first set is formed by each of the first contacts 35 which is electrically connected to a first electrical conductor 80A.

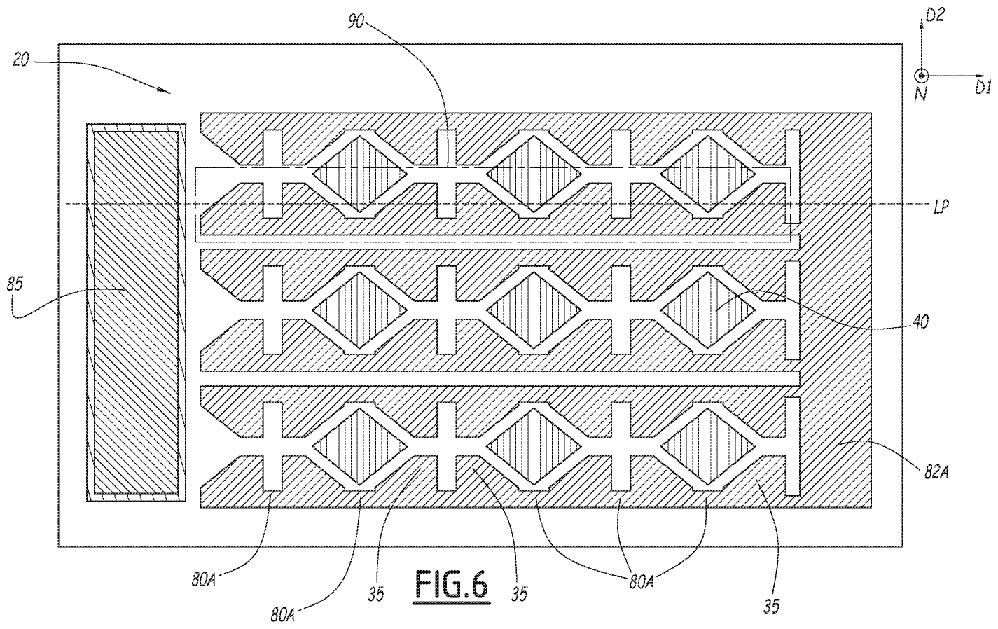

The first set includes at least two of the first contacts 35. According to the example in FIG. 6, each of the first contacts 35 belongs to the first set.

The first contacts 35 of the first set are divided into a plurality of first subsets 90. For example, each first subset 90 groups together all the first contacts 35 that are arranged along the same line LP.

A first subset 90 is identified in particular in FIG. 6 by a dotted box.

The first electrical conductors 80A electrically connect the first contacts 35 of the first set to each other. In other words, the set of first electrical conductors 80A is configured to transmit an electrical current from each first contact 35 of the first set to each other first contact 35 of the first set.

Each first electrical conductor 80A extends, for example, between two first contacts 35 of the first set. In one embodiment, at least a first electrical conductor 80A extends between a first contact 35 of the first set and the first connection pad 82A.

In particular, “extending between” two elements means that the first electrical conductor 80A is in contact with these two elements and is configured to carry an electrical current between these two elements.

According to one embodiment, each first contact 35 of the first subset is electrically connected to at least one other first contact 35 of the same first subset 90 by a first electrical conductor or conductors 80A.

For example, a first electrical conductor 80A extends between each first contact 35 of the first set and each first contact 35 belonging to the same first subset 90 and adjacent to the first contact 35 under consideration. Thus, each first contact 35 is electrically connected by the first electrical conductors 80A to each other first contact 35 of the same first subset 90, either directly by a first electrical conductor 80A extending between the two first contacts 35 under consideration, or via one or a plurality of first contact(s) 35 and the first conductor(s) 80A which extend(s) between those first contacts 35.

Each first electrical conductor 80A extends in an extension direction, which is for example the first direction D1, between two first contacts 35 of the first set. The first electrical conductor 80A has a width, measured in a direction perpendicular to the normal direction N and the direction of extension, of between 50 nm and 100 μm.

The first connection pad 82A is carried by the first face 20.

The first connection pad 82A is electrically isolated from each second contact 40.

The first connection pad 82A is electrically connected to each first contact 35 of the first set. For example, the first connection pad 82A is electrically connected to a first contact 35 of each first subset 90 by a first conductor 80A that extends between the first connection pad 82 and that first contact 35. Since each first contact 35 of each first subset 90 is electrically connected to the other first contacts 35 of the same first subset 90 by first conductors 80A, the first connection pad 82A is electrically connected to each first contact 35 of the first set.

Thus, each first contact 35 of the first set is electrically connected to each other first contact 35 of the first set by the first conductors 80A, optionally via one or a plurality of other first contacts 35 and/or via the first connection pad 82A.

It should be noted that in one conceivable variant, each first conductor 80A extends in the first direction D1 from the first connection pad 82, and is interposed in the second direction D2 between two rows of first contacts 35, each row extending in the first direction D1. The first conductor 80A is then connected to each of the first contacts 35 of these two rows.

The first connection pad 82A is provided to enable a source of electrical power to be connected to each of the first contacts 35 of the first set via the first conductor(s) 80A.

The first connection pad 82A has an area between 10 μm² . . . and 10 mm².

The third electrical contact 85 is configured such that an electrical current flowing between the third electrical contact 85 and each first contact 35 passes through the emitting structure 30 corresponding to that first contact 35. In particular, the third electrical contact 85 is electrically connected to the connection layer 72. For example, the third electrical contact 85 is electrically connected to each second contact 40.

The third contact 85 is carried by the first face 20. The third contact 85 is electrically connected to the doped layer 65 of each light emitter 10. For example, the third contact 85 extends through the substrate 12 and, optionally, through the electrically insulating layer 55, between the first face 20 and the layer 75.

Since the third contact 85 is connected to the connection layer 72 and the first connection pad 82A is connected to each first contact 35, the third contact 85 and the first connection pad 82A together provide electrical power to each light emitter 10.

In one embodiment, the first connection pad 82A and the third contact 85 together frame the first set of first contacts 35.

For example, the third contact 85, the first set of first contacts 35 and the first connection point 82A are aligned in that order along the first direction D1.

In the first injection step 130, a first electrical current is injected through each first contact 35 of the first set.

For example, a power source is electrically connected to the first connection pad 82A and the third contact 85 so as to generate a potential difference between the first connection pad 82A and the third contact 85.

It should be noted that in one embodiment, the potential difference is generated between the first connection pad 82A and one or a plurality of second contact(s) 40. This is particularly the case when each second contact 40 is electrically connected to each of the other second contacts 40, for example via the connection layer 72. For example, one of the second contacts 40 is electrically connected to the electrical source.

For example, the potential difference is greater than or equal to 3.5 volts (V).

The presence of the potential difference causes each first electric current to appear. Each first electric current passes successively through the first connection pad 82, at least one first conductor 80A, the first contact 35 under consideration and the emitting structure 30 associated with this first contact 35. The first electrical current further passes through at least one other first contact 35 and at least one other first conductor 80A which form part of an electrically conductive path connecting the first connection pad 82A to said first contact 35.

Thus, each first contact 35 of the first set and the emitting structure 30 associated with that first contact 35 each have the corresponding first current flowing through them.

Each first current is a current intended to cause the emission of the first radiation from the emitting structure 30 through which that first current flows.

The first current has an intensity. In particular, the intensity is such that each emitting structure 30 has a current density greater than or equal to 0.05 amperes per square centimetre (A/cm²).

In one embodiment of the method, the intensity is changed during the first injection step. For example, the intensity is increased from a first value to a second value.

The first value is, for example, a nominal value at which each emitting structure 30 is intended to emit the first radiation. The first value corresponds, for example, to a current density between 0.05 A/cm² and 1 A/cm².

The second value is strictly greater than the first value, for example, greater than or equal to 105 percent (%) of the first value.

In response to the injection of the first currents, the emitting structure 30 of at least one light emitter 10 is capable of emitting the corresponding first radiation. For example, each emitting structure 30 emits the corresponding first radiation.

However, there may come a time when at least one emitting structure 30 connected to a first contact 35 of the first set does not emit the first radiation, or emits a first radiation with a very low light intensity compared to the light intensity of the other emitting structures. Such an emitting structure 30 is considered defective.

At least a portion of each first emitted radiation passes through the substrate 12 in the normal direction N and through the first face 20. In particular, at least part of this first radiation passes through the first face 20 and leaves the substrate 12 via a portion of the first face 20 which does not comprise any electrically conductive layer such as, in particular, the conductive layers 87 which form the first contacts 35 and the first conductors 80A.

In particular, the first conductors 80A and the first contacts 35 are configured to allow at least some of the first radiation to pass through the first face 20. In particular, the degree of coverage of the first face 20 by the first contacts 35 and by the first conductors 80A is strictly less than 100%.

In the first observation step 140, a portion of the first radiation is observed through the first face 20. The first observation step 140 is thus implemented simultaneously with the first injection step 130.

For example, an imager is placed opposite the first face 20 and acquires an image of the first face 20 when the first currents are injected through the first contacts 35.

In particular, the imager measures a spatial variation, on the first face 20, of a light intensity of the first observed radiation. For example, for each first contact 35 of the first set, a total light intensity of an area of the first face 20 centred on the first contact 35 is measured.

The observation step 140 involves, for example, detecting a defective emitting structure 30. For example, the light intensity of each area is compared to a predetermined threshold, and an emitting structure 30 is determined to be defective when the light intensity of the area centred on the first contact 35 of the emitting structure 30 is less than or equal to the threshold.

Alternatively, varying the light intensity along a line LP, or along a line segment parallel to the second direction D2, is another method of observing the first radiation that can detect a defective emitting structure 30.

In one embodiment, the first wavelength range associated with the first radiation observed in the area centred on each first contact 35 is determined. For example, a spectral study is carried out in which light intensity is measured as a function of wavelength or photon energy.

In the removal step 150, each first conductor 80A is removed.

For example, each first 80A conductor is removed by etching. Etching involves exposing each first conductor 80A to a fluid such as a gas, liquid, or plasma, so as to remove the material(s) making up the first conductor 80A.

In particular, the layer(s) 87 forming each first conductor 80A, i.e. the layer(s) 87 deposited during the forming step 120, are removed by etching.

The etching is, for example, plasma etching, or wet chemical etching through a lithography mask.

In particular, a second mask, e.g. of a photosensitive resin, is applied to the first face 20. The second mask covers each first contact 35, and does not cover the first conductors 80A. During etching, the mask-covered first face 20 is exposed to the fluid so as to remove the exposed materials and leave the materials, including the first contacts 35, protected by the second mask unchanged.

With the invention, the emitting structures 30 of the first set are electrically connected in a simple manner to an electrical source since the associated first contacts 35 are electrically connected to each other. Thus, it is not necessary to individually connect each first contact 35 of the first set to the electrical source via a respective connector such as a wire or a pin. Only one such connector, in contact with one of these first contacts 35, with one of the first conductors 80A or with the first contact pad 82A, is needed to inject an electric current into each of the emitting structures 30 of the first set.

This is further facilitated if the third contact 85 is electrically connected to each cover layer 50, because in such a case it is not necessary to connect each second contact 40 to the electrical source in parallel.

Thus, it is possible to simply trigger a light emission from each of the emitting structures 30 at a relatively early stage in a method of manufacturing a device comprising one or more light emitters. Indeed, it is not necessary to wait for the light emitter(s) 10 to be connected to the control circuit of this device. In particular, it is not necessary for the light emitters 10 in the set to have been separated from each other and then individually electrically connected to the control circuit.

This makes it possible to detect defective emitting structures 30, or to measure a spectrum of the first radiation of each emitting structure 30 in order to accordingly adapt the device into which these emitting structures 30 would then be integrated. For example, it is possible to group the light emitters 10 together to form pixels based on the measured spectra, for example to ensure a good white balance of the pixel.

Furthermore, in many methods, the set of light emitters 10 is attached to a holding device in such a way as to leave the first face 20 exposed to allow deposition of the first contacts 35, so that the third face 25, which is intended to pass radiation during nominal operation of the light emitters 10, is not accessible. By observing the first radiation through the first face 20, it is not necessary to unhook the whole holding device to observe the third face 25, which also makes the method faster.

The increase, during the first injection step, of the intensity of the first currents from the first value to the second value, allows the detection of emitting structures 30 which would be likely not to operate at the first value but which would operate at the second value. Such structures may still be used in devices, and it is worthwhile not to simply dismiss them as defective and discard them.

The etching allows the simple removal of each of the first conductors 80A. It is sufficient to design a second mask to reveal each of the first conductors 80A and to cover each of the first contacts 35.

Measuring the light intensity of the area centred on a first contact 35 is a simple method of detecting a defective emitting structure 30.

A second example manufacturing method will now be described. The same elements as in the first example are not described again; only the differences are highlighted.

During the formation step 120 at least a second set of first contacts 35, disjoint from the first set, is also defined.

In addition, a set of second conductors 80B is formed on the first face 20, and optionally a second contact pad 82B is formed on the first face 20. The second conductors 80B and, optionally, the second contact pad 82B are in particular produced simultaneously with the first conductors 80A via the deposition of one or more layers 87 of the same material(s).

The second group includes all the first contacts 35 which are connected to each other by second conductors 80B.

The second set includes at least two of the first contacts 35. “Disjoint” means that no first contact 35 belongs to both the first set and the second set. Thus, no first contact 35 is electrically connected to a first conductor 80A and to a second conductor 80B. As a result, the first and second sets are electrically isolated from each other.

In one embodiment, each first contact 35 belongs to the first set or the second set. For example, a number of first contacts 35 in the first set is identical to a number of first contacts 35 in the second set.

Each first contact 35 of the second set is electrically isolated from each first contact 35 of the first set.

The first contacts 35 of the second set are divided into a plurality of second subsets 95. For example, each second subset 95 groups together all the first contacts 35 that are arranged along the same line LP.

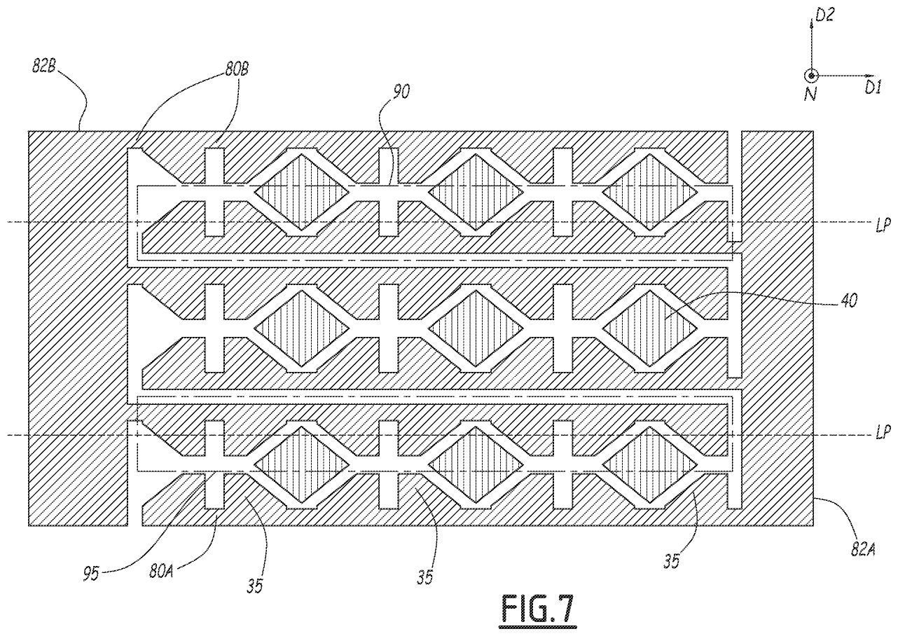

A second subset 95 is identified in particular in FIG. 7 by a dotted box.

In one embodiment, the line LP of the first subsets 90 and the second subsets 95 alternate along the second direction D2. In other words, a single first subset 90 is interposed between each pair of successive second subsets 95, and a single second subset 95 is interposed between each pair of successive first subsets 95.

The second electrical conductors 80B electrically connect the first contacts 35 of the second set to each other. In other words, the set of second electrical conductors 80B is configured to transmit an electrical current from each first contact 35 of the second set to each other first contact 35 of the second set.

Each second electrical conductor 80B extends, for example, between two first contacts 35 of the second set. In one embodiment, at least one second electrical conductor 80B extends between a first contact 35 of the second set and the second connection pad 82B.

According to one embodiment, each first contact 35 of the second subset is electrically connected to at least one other first contact 35 of the same second subset 95 by one or more second electrical conductor(s) 80B.

For example, a second electrical conductor 80B extends between each first contact 35 of the second set and each first contact 35 belonging to the same second subset 95 and adjacent to the first contact 35 under consideration. Thus, each first contact 35 of the second set is electrically connected by the second electrical conductors 80B to each other first contact 35 of the same second subset 95, either directly by a second electrical conductor 80B extending between the two first contacts 35 under consideration, or via one or a plurality of first contact(s) 35 and the second conductor(s) 80B which extend(s) between those first contacts 35.

Each second electrical conductor 80B extends in an extension direction, which is for example the first direction D1. The second electrical conductor 80B has a width, measured in a direction perpendicular to the normal direction N and the direction of extension, of between 50 nm and 1 mm.

The second connection pad 82B is carried by the first face 20.

The second connection pad 82B is electrically connected to each first contact 35 of the second set. For example, the second connection pad 82B is electrically connected to a first contact 35 of each second subset 95 by a second conductor 80B that extends between the second connection pad 82 and that first contact 35. Since each first contact 35 of each second subset 95 is electrically connected to the other first contacts 35 of the same second subset 95 by second conductors 80B, the second connection pad 82B is electrically connected to each first contact 35 of the second set.

Thus, each first contact 35 of the second set is electrically connected to each other first contact 35 of the second set by the second conductors 80B, optionally via one or a plurality of other first contacts 35 and/or via the second connection pad 82B.

For example, each first contact 35 is interposed along the first direction D1 between the first connection pad 82A and the second connection pad 82B.

The second connection pad 82B is provided to enable a source of electrical power to be connected to each of the first contacts 35 of the second set via the second conductor(s) 80B.

The first connection pad 82B has an area between 10 μm² and 10 mm².

The method comprises a second injection step 160 and a second observation step 170.

In the second injection step 160, a second electrical current is injected through each first contact 35 of the second set.

The second injection step 160 is staggered in time with respect to the first injection step 130. In particular, no second current is injected simultaneously with a first current.

For example, a power source is electrically connected to the second connection pad 82B and the third contact 85 so as to generate a potential difference between the second connection pad 82B and the third contact 85.

For example, the potential difference is greater than or equal to 3.5V.

The presence of the potential difference causes each second electric current to appear. Each second electric current passes successively through the second connection pad 82B, at least one second conductor 80B, the first contact 35 under consideration and the emitting structure 30 associated with this first contact 35. The first electrical current further passes through at least one other first contact 35 and at least one other second conductor 80B which form part of an electrically conductive path connecting the second connection pad 82B to said first contact 35.

Thus, each first contact 35 of the second set and the emitting structure 30 associated with that first contact 35 each have the corresponding second current flowing through them.

Each second current is a current intended to cause the emission of the first radiation from the emitting structure 30 through which that second current flows.

The second current has an intensity. The intensity corresponds to a current density greater than or equal to 0.05 A/cm².

In one embodiment of the method, the intensity is changed during the second injection step 160. For example, the intensity is increased from a first value to a second value.

In response to the injection of the second currents, the emitting structure 30 of at least one light emitter 10 of the second set is capable of emitting the corresponding first radiation. For example, each emitting structure 30 emits the corresponding first radiation. However, some of the emitting structures 30 may also be defective and not emit the first radiation.

In a similar manner to the first injection step 130, the first radiation emitted by the emitting structures 30 of the light emitters of the first set passes at least partially through the first face 20.

In the second observation step 170, such first radiation is observed. The second observation step 170 is thus implemented simultaneously with the second injection step 160.

In particular, a defective emitting structure 30 is detected when a total light intensity of an area of the first face 20 centred on the first contact 35 under consideration is less than or equal to the threshold.

In the removal step 150, each second conductor 80B is removed simultaneously with the first conductors 80A.

The use of two separate sets of first contacts 35 in the manufacturing step 110 makes it possible, during the injection steps 130, 160 and the observation steps 140, 170, to power only a portion of the first contacts 35, and thus the emitting structures 30, at any one time.

This keeps the observation of light passing through a zone centred on a first contact 35 on the first face 20 from being polluted by the presence of first radiation emitted by another first contact 35 that is too close, by not powering all the first contacts 35.

It turns out that an arrangement in which each first or second subset 90, 95 includes the first contacts 35 arranged along the same line, these first or second subsets being alternated along the second direction D2, makes it possible to effectively detect a defective emitting structure, since this emitting structure 30 is framed, along the second direction D2, by two emitting structures 30 which are not powered.

When the first contacts 35 are interposed between the two connection pads 82A and 82B, it is particularly easy to manufacture the first and second sets.

The use of connection pads 82A, 82B to inject the first and/or second currents avoids damaging the first contacts 35 in these steps by applying a spike or terminal connection to the power source. The subsequent contact between the first contacts 35 and the control circuit is then improved and the reliability of the resulting display is enhanced.

When a plurality of second contacts 40 are electrically connected to each other, in particular when all second contacts 40 are electrically connected to each other, the injection steps 130, 160 are made simpler since the number of electrical connections to be made between the power supply and the first and second contacts 35, 40 is limited. When all second contacts 40 are electrically connected to each other, each injection step 130, 160 is implemented with only two electrical connections, and is therefore particularly easy to implement.

In particular, observation of the radiation emitted through the first face allows observation to be carried out while the wafer 11 and the set of light emitters 10 thereon are attached to a handle that limits access to the second face 22.

It should be noted that, although the manufacturing method has been described above in the case where the first contacts 35 of each first or second subset 90 are connected to each other by conductors 80A, 80B extending in the first direction D1, other configurations are possible.

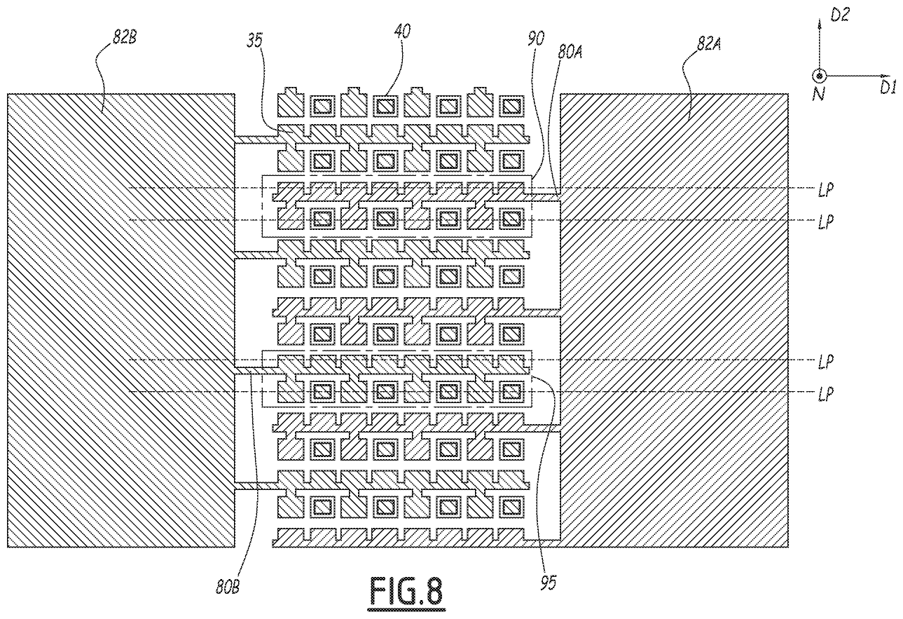

For example, as shown in FIG. 8, each first subset 90 includes each of the first contacts 35 which extend along two adjacent lines LP. Each first conductor 80A extends between the two lines LP of a corresponding first subset 90 and is connected to each of the first contacts 35 arranged along these two line.

In addition, each second subset 95 includes each of the first contacts 35 which extend along two adjacent lines LP. Each second conductor 80B extends between the two lines LP of a corresponding second subset 95 and is connected to each of the first contacts 35 arranged along these two line.

In addition, the arrangement of the first and second contacts 35, 40 on the first face 20 may vary.

For example, as shown in FIG. 8, the first and second contacts 35, 40 form a square mesh array wherein a pattern is repeated on the first face 20, each pattern comprising three first contacts 35 and a second contact 40 each arranged at a corner of a square. It should be noted that other configurations are still possible.

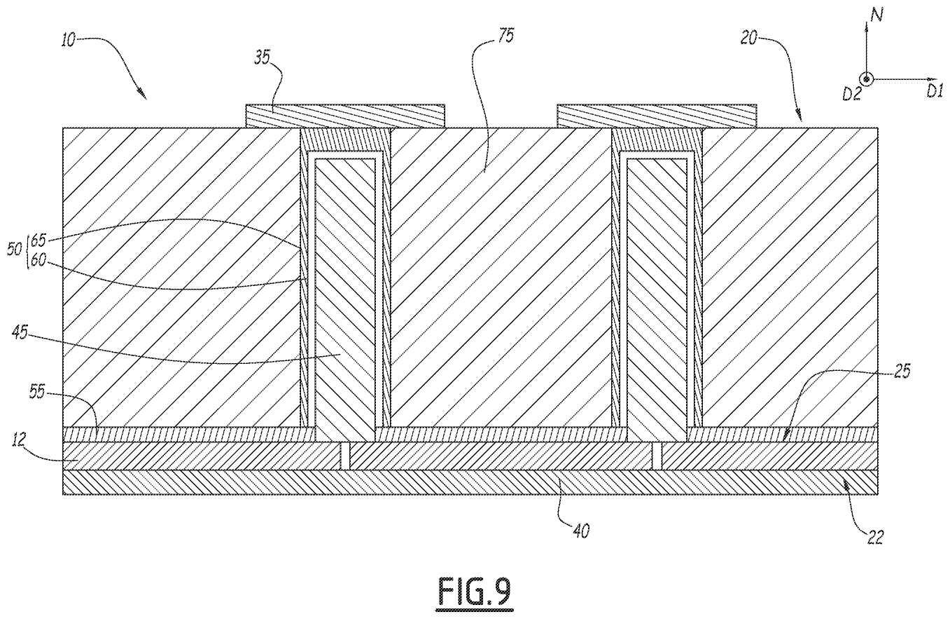

In another embodiment, each first contact 35 is connected to the anode of the corresponding emitting structure 30, as shown in FIG. 9.

For example, each first contact 35 is borne by the layer 75 and connected to the doped layer 65 of the corresponding emitting structure 30. In particular, the first contact 35 is in contact with a portion of the doped layer 65 that is aligned with the core 45 along the normal direction N.

In this case, the first face 20 is a face of the layer 75. In particular, the layer 75 is bounded by the first face 20 and the third face 25. The substrate 12 is in such a case bounded in the normal direction N by the second face 22 and the third face 25.

In this case, the coverage rate of the first contacts 35 is, for example, between 1% and 99%.

Each second contact 40 is, for example, borne by the second face 22. For example, each second contact 40 is common to each light emitter 10. In particular, the second contact 40 is a layer covering the second face 22 and electrically connected to the n-doped layer(s) of each emitting structure 30.

Each second contact 40 is, for example, made of aluminium.

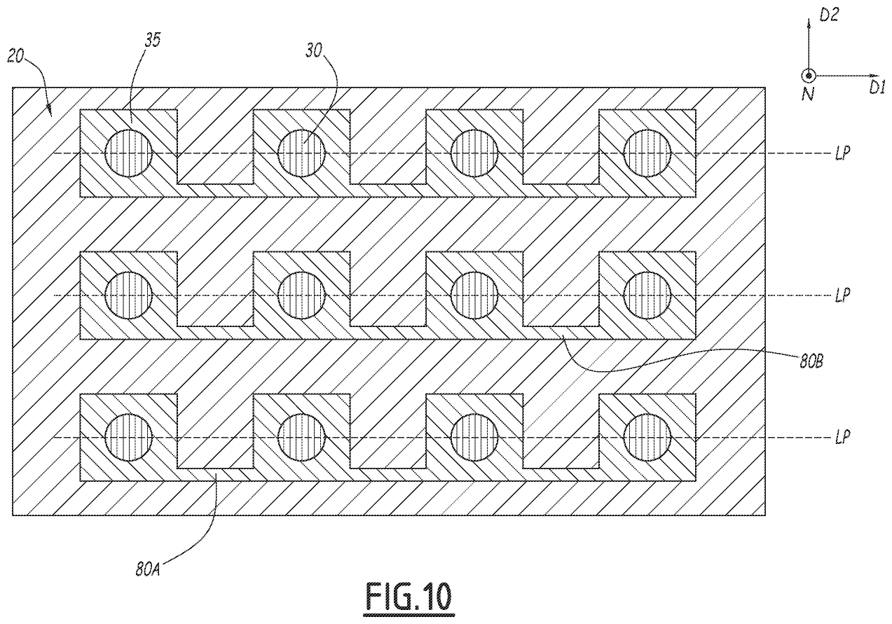

In the forming step 120, the first contacts 35 are in particular connected to each other by first or second conductors 80A, 80B each extending along the first direction D1, as shown in FIG. 10.

It should be noted that, although the emitting structures 30 have been described in the previous examples as three-dimensional emitting structures, in particular microwires, other types of emitting structures 30 may be considered.

For example, each emitting structure is a two-dimensional structure formed by a stack of layers borne by the substrate 12. In this case, each layer extends in a plane perpendicular to the normal direction N. In particular, the layers are common to each emitting structure 30.

Furthermore, the first and second subsets 90, 95 have been described in the case of a two-dimensional square mesh array formed by the first contacts 35. It should be noted that these subsets may also be alternated along the second direction D2 in the case of arrays with a non-square mesh, for example a triangular, hexagonal or rectangular mesh.

It should be noted that each of the above processes is capable of being implemented in a method for producing a display screen comprising a step of providing a control circuit, a step of implementing the manufacturing method, a separation step, a disposal step, and a connection step. The display screen has a plurality of light emitters 10, for example grouped as pixels 15.

In the step of providing the control circuit, a control circuit for selectively powering a plurality of light emitters 10 is provided.

In the separation step, at least one light emitter 10 of the manufactured set is separated from at least one other light emitter 10. For example, the wafer 11 is cut to separate at least one light emitter 10 from at least one other light emitter 10, for example from each other light emitter 10.

Alternatively, the light emitters 10 in the set are separated from each other so that each light emitter 10 is mechanically independent of each other light emitter 10. For example, the wafer 11 is cut to separate the light emitters 10 from each other.

In another embodiment, at least one pixel 15 is separated from at least one other pixel 15. For example, the wafer 11 is cut to separate at least one pixel 15 from at least one other pixel 15, for example from each other pixel 15.

The pixels 15 are separated from each other, for example by cutting the wafer 11.

By “a pixel 15 separated from at least one other pixel 15” it is meant that the light emitters 10 of the pixel 15 in question are mechanically connected to each other but are not mechanically connected to the light emitters 10 of the other pixel 15. This is achieved, for example, by cutting the wafer 11 around the light emitters 10 of the pixel to be separated.

In the disposal step, at least one light emitter 10 identified as defective during an observation step 140, 170 is discarded.

For example, each light emitter 10 identified as defective is discarded. In particular, each pixel 15 including at least one defective light emitter 10 is discarded.

In particular, “discarded” means that each discarded light emitter 10 or pixel 15 is not taken into account for the implementation of the steps subsequent to the disposal step. For example, each discarded light emitter 10 or pixel 15 is isolated from the light emitters 10 or pixels 15 that are not defective, discarded, or destroyed in the disposal step.

In particular, the connection step can be carried out after the disposal step and is therefore only carried out for non-discarded light emitters 10 or pixels 15.

During the connection step, at least one non-defective light emitter 10 is selected. This light emitter 10 is, in particular, a light emitter 10 that has not been discarded. This light emitter 10 is connected to the control circuit in the connection step. In particular, the first contact 35 and the second contact 40 of the light emitter 10 are each connected, directly or indirectly, to a connection pad of the control circuit so that the control circuit is able to inject an electric current into the emitting structure 30.

Alternatively, in the connection step, at least one pixel 15 including only non-defective light emitters 10 is selected, each light emitter 10 of the selected pixel(s) 15 being connected to the control circuit in the connection step.

In one embodiment, each of the first and second contacts 35, 40 of the non-discarded set of light emitters 10 is connected to a connection pad of the control circuit.

In the connection step, the selected light emitters 10 and/or pixels 15 are connected to the control circuit to obtain a display screen or part of a display screen.

Furthermore, although in the previous examples the second contacts 40 have been described as being arranged on the surface of the substrate 12, in particular on the second face 22, other embodiments are possible.

For example, in one embodiment, the second contacts 40 are accommodated within the substrate 12, in particular interposed between the first face 20 and the second face 22. In particular, the contacts 35 and 40 are arranged on two separate metal layer levels, with the first contacts 35 being arranged on an outer metal layer level of the substrate 12 while the second contacts 40 are arranged on an inner metal layer level of the substrate 12.

In one embodiment, the removal step 150 is not carried out. In this case, at least two first contacts 35 of two separate light emitters 10 are electrically connected to each other after the manufacturing method. For example, the light emitters 10 are not separated from each other.

This variant applies in particular in a case where the light emitters 10 are connected to the same electrode of the control circuit. This simplifies the manufacture of the set of light emitters 10, as it is not necessary to connect each first contact 35 individually to the control circuit.

In one embodiment, the second contacts 40 are electrically disconnected from each other and each connected to a separate electrode of the control circuit in order to control the light emitters 10 individually.

The injection 130, 160 and observation 140, 170 steps are, for example, implemented by a test device comprising the power source, the imager and an electronic control module.

The control module is configured to order the source to inject the first current and/or the second current in the injection steps 130 and 160.

In addition, the control module is configured to receive from the imager the image(s) acquired during the first observation step 140 and/or the second observation step 170. In particular, the control module is configured to detect, from the received image(s), at least one defective emitting structure 30 during the first observation step 140 and/or the second observation step 170.

In particular, the control module is configured to store in a memory, during the first observation step 140 and/or the second observation step 170, at least one piece of information relating to the position of each defective emitting structure 30 detected.

The information includes, for example, a set of spatial coordinates of the faulty emitting structure 30. Alternatively, the information comprises an identifier of the faulty emitting structure 30, for example a number of the faulty emitting structure 30.

The control module comprises, for example, in addition to the memory, a processor adapted to execute software instructions stored in the memory to implement the injection 130, 160 and observation 140, 170 steps.

Alternatively, the control module comprises, in addition to the memory, a set of dedicated integrated circuits and/or programmable logic components, this set being suitable for controlling the implementation of the injection 130, 160 and observation 140, 170 steps.

It should also be noted that, although the set of light emitters 10 is described above in a case where all fourth contacts 40 are connected to the third contact 85 by the connection layer 72, embodiments without a connection layer 72 are also possible.

For example, the fourth contacts 40 are connected to the third contact 85 by a set of conductors made of a metallic material. These conductors are, for example, incorporated into the wafer 11 supplied in the supply step 100, or manufactured on either of the faces 20 and 22 in the manufacturing step 110.

It should also be noted that embodiments in which not all second contacts 40 are connected to each other are also considered. For example, two or more groups of second contacts 40 are present, the second contacts 40 of each group being connected to each other and being electrically isolated from the second contacts 40 of each other group.

Furthermore, in some embodiments, the radiation emitted during the injection steps 130, 160 is likely to be observed through a face other than the first face 20, in particular through the face 25.

### GLOSSARY

DOPING

Doping is defined as the presence of impurities in a material that provide free charge carriers. Impurities are, for example, atoms of an element that is not naturally present in the material.

When impurities increase the volume density of holes in the material, compared to undoped material, the doping is called p-doping. For example, a gallium nitride layer, GaN, is p-doped by adding magnesium (Mg) atoms.

When impurities increase the volume density of free electrons in the material, compared to the undoped material, the doping is called n-doping. For example, a layer of gallium nitride, GaN, is n-doped by adding silicon (Si) atoms.

LED STRUCTURE

An LED structure is a semiconductor structure including a plurality of semiconductor regions forming a P-N junction and configured to emit light when an electric current flows through the individual semiconductor regions.

A two-dimensional structure including an n-doped layer, a p-doped layer and at least one emitting layer is an example of an LED structure. In this case, each emitting layer is interposed along the normal direction N between the n-doped layer and the p-doped layer.

In one embodiment, each emitting layer has a bandgap value strictly less than the bandgap value of the n-doped layer and strictly less than the bandgap value of the p-doped layer. For example, the n-doped layer and the p-doped layer are GaN layers, and each emitting layer is an InGaN layer.

The emitting layer is, for example, undoped. In other embodiments, the emitting layer is doped.

A quantum well is a specific example of an emitting layer with a bandgap value lower than the bandgap values of the n- and p-doped layers.

QUANTUM WELL

A quantum well is a structure in which quantum confinement occurs, in one direction, for at least one type of charge carrier. The effects of quantum confinement occur when the size of the structure along this direction becomes comparable to or smaller than the De Broglie wavelength of the carriers, which are usually electrons and/or holes, leading to energy levels called “energy subbands”.

In such a quantum well, the carriers may only have discrete energy values but are generally able to move within a plane perpendicular to the direction in which confinement occurs. The energy values available to the carriers, also called “energy levels”, increase as the dimensions of the quantum well decrease along the direction in which confinement occurs.

In quantum mechanics, the “De Broglie wavelength” is the wavelength of a particle when the particle is considered as a wave. The De Broglie wavelength of electrons is also called the “electron wavelength”. The De Broglie wavelength of a charge carrier depends on the material of which the quantum well is made.

An emitting layer whose thickness is strictly less than the product of the electron wavelength of the electrons in the semiconductor material of which the emitting layer is made and five is an example of a quantum well.

Another example of a quantum well is an emitting layer whose thickness is strictly less than the product of the De Broglie wavelength of excitons in the semiconductor material of which the emitting layer is made and five. An exciton is a quasi-particle including an electron and a hole.

In particular, a quantum well often has a thickness between 1 nm and 200 nm.

### SEMICONDUCTOR MATERIAL

The term “band gap value” should be understood to be the band gap value between the valence and conduction band of the material.

The band gap value is, for example, measured in electronvolts (eV).

The valence band is defined as the band with the highest energy of the energy bands that are allowed for electrons in the material and which is completely filled at a temperature of 20 Kelvin (K) or less.

A first energy level is defined for each valence band. The first energy level is the highest energy level of the valence band.

The conduction band is defined as the lowest energy band of the energy bands allowed for electrons in the material, which is not completely filled at a temperature of 20 K or less.

A second energy level is defined for each conduction band. The second energy level is the highest energy level of the conduction band.

Thus, each band gap value is measured between the first energy level and the second energy level of the material.

A semiconductor material is a material with a band gap value strictly greater than zero and less than or equal to 6.5 eV.

An example of a semi-conductor material is a direct band gap semiconductor. A material is considered to have a “direct band gap” when the minimum of the conduction band and the maximum of the valence band correspond to the same value of charge carrier momentum. A material is considered to have an “indirect band gap” when the conduction band minimum and valence band maximum correspond to different charge carrier momentum values.

Each semiconductor material may be selected, for example, from the group of III-V semiconductors, in particular III-nitrides, II-VI semiconductors, or IV-IV semiconductors.

III-V semiconductors include InAs, GaAs, AIAs and their alloys, InP, GaP, AIP and their alloys, and III-nitrides.

II-VI semiconductors include CdTe, HgTe, CdSe, HgSe, and their alloys.

IV-IV semiconductors include Si, Ge and their alloys.

THREE-DIMENSIONAL STRUCTURE

A three-dimensional structure is a structure that extends along a main direction. The three-dimensional structure has a length measured along the main direction. The three-dimensional structure also has a maximum lateral dimension measured along a lateral direction perpendicular to the main direction, the lateral direction being the direction perpendicular to the main direction along which the dimension of the structure is greatest.

The maximum lateral dimension is, for example, less than or equal to 10 micrometers (μm), and the length is greater than or equal to the maximum lateral dimension. The maximum lateral dimension is advantageously less than or equal to 2.5 μm.

In particular, the maximum lateral dimension is greater than or equal to 10 nm.

In specific embodiments, the length is greater than or equal to twice the maximum lateral dimension, for example it is greater than or equal to five times the maximum lateral dimension.

The main direction is, for example, the normal direction N. In this case, the length of the three-dimensional structure is called “height” and the maximum dimension of the three-dimensional structure, in a plane perpendicular to the normal direction N, is less than or equal to 10 μm.

The maximum dimension of the three-dimensional structure, in a plane perpendicular to the normal direction N, is often referred to as the “diameter” regardless of the shape of the cross-section of the three-dimensional structure.

For example, each three-dimensional structure is a microwire. A microwire is a cylindrical three-dimensional structure.

In one specific embodiment, the microwire is a cylinder extending along the normal direction N. For example, the microwire is a cylinder with a circular base. In this case, the diameter of the base of the cylinder is less than or equal to half the length of the microwire.

A microwire with a maximum lateral dimension of less than 1 pm is called a “nanowire”.

Another example of a three-dimensional structure is a pyramid extending along the normal direction N from the substrate 12.

Another example of a three-dimensional structure is a cone extending along the normal direction N.

Another example of a three-dimensional structure is a truncated cone or a truncated pyramid extending along the normal direction N.

1. A method for manufacturing a set of light emitters, each light emitter comprising a light emitting structure, a first electrical contact and a second electrical contact, the method comprising the steps of:
providing a wafer carrying a set of light emitting structures, the wafer having a first face and a second face, the first face and the second face bounding the wafer in a direction normal to the wafer, each emitting structure being configured to emit a first radiation when an electric current flows through the emitting structure, and
manufacturing a first electrical contact and a second electrical contact for each emitting structure, the first contact being arranged on the first face, the first contact and the second contact being configured so that, when an electrical potential difference is imposed between the first contact and the second contact, an electrical current flows through the emitting structure, the first contacts being electrically insulated from each other,
the method being wherein the manufacturing step comprises:
a step of forming, on the first face, each first contact and at least one first conductor, a first set of at least two first contacts being defined, each first contact of the first set being electrically connected to each other first contact of the first set by the first conductor,
a first step of injecting, for each first contact belonging to the first set, a first electric current through said first contact and the emitting structure corresponding to said first contact, and
a first step of observing a radiation emitted by at least one emitting structure in response to the injection of the first electric current.

2. The method according to claim 1, further comprising, following the first observation step, a step of removing each first conductor.

3. The method according to claim 2, wherein the forming step comprises depositing on the first face a layer of electrically conductive material to form each first contact and each first conductor, each first conductor being removed in the removing step by etching said layer.

4. The method according to claim 1, wherein each first contact is disposed opposite the corresponding emitting structure.

5. The method according to claim 2, wherein a second set of first contacts is further defined comprising at least two first contacts, the first set and the second set being distinct, the forming step comprising the formation of at least one second conductor, each first contact of the second set being electrically connected to each other first contact of the second set by the second conductor, the method further comprising a second step of injecting, for each first contact belonging to the second set, a second electric current through the first contact in question and the emitting structure corresponding to said first contact, and a second step of observing, through the first face, a radiation emitted by at least one emitting structure in response to the injection of the second electric current.

6. The method according to claim 5, wherein the first set comprises a plurality of first subsets, the second set comprising a plurality of second subsets, the first contacts of each first or second subset being arranged along a line of said subset, each line extending in a first direction on the first face, the lines being parallel to each other and offset from each other in a second direction perpendicular to the first direction, the lines of the first and second subsets alternating in the second direction.

7. The method according to claim 6, wherein the forming step further comprises forming a first connection pad and a second connection pad on the first face, the first connection pad being electrically connected to each first conductor, the second connection pad being electrically connected to each second conductor, each first electrical current being injected via the first connection pad, each second electrical current being injected via the second connection pad.

8. The method according to claim 7, wherein the set of first contacts is interposed between the first connection pad and the second connection pad along the first direction.

9. The method according to claim 5, wherein the removal step comprises removing each second conductor.

10. The method according to claim 5, wherein each first contact belongs to the first or second set.

11. The method according to claim 1, wherein in the first observation step, and/or in the second observation step if any, the emitted radiation is observed through the first face.

12. The method according to claim 1, wherein the first injection step, and/or the second injection step if any, comprises the modification of an intensity of the first current between a first value and a second value strictly greater than the first value.

13. The method according to claim 12, wherein each emitting structure comprises a light-emitting diode, each first electrical contact being notably electrically connected to a cathode of the light-emitting diode.

14. The method according to claim 1, wherein the set of light emitters comprises a single second contact common to all the light emitters.

15. The method according to claim 1, wherein the set of light emitters comprises a plurality of second contacts.

16. The method according to claim 15, wherein during the first injection step and/or the second injection step if any, at least two second contacts are electrically connected to one another.

17. The method according to claim 16, wherein the first observation step, and/or the second observation step if any, comprises a step of detecting a defective emitting structure.

18. The method according to claim 17, wherein the first observation step comprises measuring, for each first contact, a light intensity of radiation passing through the first face in an area surrounding the first contact, and detecting a defective emitting structure when the measured light intensity is strictly below a predetermined threshold.

19. The method according to claim 17, wherein the detection step comprises storing, in a memory, information relating to the positioning of at least one defective emitting structure.

20. The method according to claim 19, comprising a step of separating the light emitters from each other and a step of disposing of each light emitter that is defective according to the stored information.

21. The method according to claim 20, the method further comprising:
a step of providing a control circuit, and
a step of connecting the first electrical contact and the second electrical contact of each light emitter to the control circuit.

22. The method according to claim 21, wherein the connection step is carried out after the disposal step.
